(19) United States
(12) Patent Application Publication
(10) Pub. No.: US 2004/0076302 A1
(43) Pub. Date: Apr. 22, 2004

(54) Device for the noise-dependent adjustment of sound volumes

(76) Inventor: Markus Christoph, Straubing (DE)

Correspondence Address: WARE FRESSOLA VAN DER SLUYS &, ADOLPHSON, LLP, BRADFORD GREEN BUILDING 5, 755 MAIN STREET, P O BOX 224, MONROE, CT, 06468, US

(21) Appl. No.: 10/466,292

(22) PCT Filed: Feb. 14, 2002
(86) PCT No.: PCT/EP02/01591

(30) Foreign Application Priority Data
Feb. 16, 2001 (DE) 101 07 385.2

(51) Int. Cl. H03G 3/00; H03G 3/20

(52) U.S. Cl. 381/57; 381/108

(57) ABSTRACT

The invention relates to a device for the noise-dependent adjustment of the sound volume of a loudspeaker (8) fed with an electrical useful signal (2, 9) from a signal source (1) on a location of listening that is filled by noise (17). The inventive device comprises two sound volume adjusters (3, 5) that are connected in series and between the signal source (1) and the loudspeaker (8). One of said adjusters (3) can be manually controlled and the other (5) is controlled by a control signal (18). A noise detector (6) determines the noise level (17) and generates the control signal (18) for the other sound volume adjuster (5) in accordance with the noise level (17).

The invention concerns a device for the noise-dependent adjustment of the sound volume of a loudspeaker which is fed a useful electric signal from a signal source in a listening area that is filled with noise.

When an electro-acoustic device introduces music or speech in an environment filled with noise, the background noise usually disturbs the listening pleasure. For example the inside of a motor vehicle is a noise-filled room in which music and speech are often listened to. Here the background noise can be caused by the engine, the tires, the fan and other devices in the motor vehicle and is therefore dependent on the speed, the road conditions and the operating conditions inside the motor vehicle.

The occupant of a motor vehicle handles this noise environment which changes with time, for example by adapting the useful signals offered in the form of music and speech by turning the sound volume control accordingly. A simple increase in the sound volume however does not solve the problem because it then causes a loss in the bass signal perception. The undesirable background noise in the vehicle hides the desirable useful signals and leads to a change in the perceived sound.

A device is known from U.S. Pat. No. 5,034,984, wherein two sound volume adjusters are connected between the signal source and the loudspeaker, where one of them can be manually controlled while the other can be controlled by a predetermined control signal. This control signal is derived from the motor vehicle speed. It is assumed in this case that the speed approximately represents the noise level in the vehicle. But the speed is only a very inaccurate representative of the noise, because the noise environment caused for example at the same speed by asphalt, cobblestone and gravel surfaces is very different.

For that reason in another connection U.S. Pat. No. 4,944,018 suggests to additionally read other vehicle signals which represent noise, such as for example the engine r.p.m. or the operating condition of a fan. But these factors also provide only relatively little information about the actual noise environment in the vehicle. In that case external factors in particular, such as the already mentioned roadway cover are not taken into consideration, even though they have a significant effect on the noise inside the vehicle.

It is therefore the object of the invention to present a device of the above mentioned type which offers an improved adaptation of the sound volume to the actual noise environment.

The object is achieved by a device as claimed in patent claim 1. Further versions and developments of the inventive idea are the subject of subclaims.

In detail the device of the invention comprises two sound volume adjusters connected in series to each other and between the signal source and the loudspeaker, one of which can be manually controlled (directly or indirectly) and the other can be controlled by a control signal (automatic). A noise detector is also provided to determine the level of the noise and to produce a control signal for the other sound volume adjuster in accordance with the noise level.

In this way the desired level can be manually adjusted in a simple manner for a predetermined noise situation, which is then automatically and accordingly adapted when the noise situation changes. Beyond that the separation between manual and automatic sound volume adjustment has the advantage that a usually provided tone-compensated adaptation of the sound at low sound levels can be undertaken in a simple and effective manner.

Although the exact course of the noise signal at the frequency cannot be predicted, as a rule there is a course which corresponds to that of pink noise. Depending on whether one or several windows of the vehicle are open or closed, whether the vehicle's vent is turned on, at which stage the vent is operated and in what direction the fan is presently blowing, the result are of course shifts in the noise spectrum, but the main course which corresponds to that of pink noise remains in effect. Pink noise means that the main energy of the spectrum has settled in the low frequency spectral region and decreases toward the higher frequencies.

Since typical vehicle noises in the low-frequency spectral region contain a very high portion of energy, they also incur stronger spectral masking in those areas than in the remaining spectral regions. Most of these masking effects can be compensated with suitable tone-compensated adaptations of the transmission function, particularly by boosting the lower tones. The inventive use of two separate sound volume adjusters has the advantageous effect that one of the sound volume adjusters can be used to set the sound volume desired by the operator, while the respective tone-compensated adaptation (corresponding to a loudness curve) is also adjusted at the same time. The second sound volume adjuster is exclusively controlled dynamically as a function of the noise level. The result achieves a very close adaptation to the characteristics of human hearing.

The effect is as follows: if an operator adjusts a predetermined sound volume in the vehicle, a tone-compensated adaptation takes place in accordance with a corresponding loudness curve as well. The lower the sound volume chosen by the operator, the more the bass response is boosted. And conversely, the higher the sound volume chosen by the operator, the less the bass response is boosted. For example if the operator chooses a relatively low sound volume, a relatively large bass boost is produced. If the noise level in the vehicle now increases due to a change in the roadway cover, or by opening a window, turning on the vent, increasing the speed, racing the individual gears, etc., the sound volume increases with the help of the second sound volume adjuster, which may be installed before or behind the first sound volume adjuster.

In that case the loudness curve established by the manual sound volume adjuster remains unchanged, so that an increase in bass boost takes place by and large when the noise level increases, as opposed to a loudness curve without any noise effect. But as already mentioned earlier, since a noise level increase in motor vehicles usually matches a heavier masking of the lower frequency portions (pink noise), it is precisely these frequency portions which must be reinforced or boosted. This achieves that regardless of which noise situation takes place, the operator always experiences the same sound impression, particularly in the bass region.

The usual loudness curve has a cut-off frequency at about 50 Hz, which must however be seen as too low for a typical noise effect in the vehicle. It is therefore preferred to correct the existing loudness curve as a function of the prevailing background noise. In this case the correction can take place as a function of the momentarily prevailing noise level, for example by changing the filter quality, the filter cut-off frequency, or also by switching on one or more filters.

Thus the manually controllable sound volume adjuster benefits the invention further by means of a unit for the tone-compensated adaptation of the transmission function between the signal source and the loudspeaker, which is coupled to the adjusted sound volume, and/or a unit for the tone-compensated adaptation of the transmission function which is connected between the signal source and the loudspeaker, where the unit for the tone-compensated adaptation is controlled by at least one (further) control signal from the noise detector.

In that case the unit for the tone-compensated adaptation of the transmission function can comprise at least two filters (e.g. band-pass filters) with different cut-off or mid-frequencies, which are (each) controlled by a control signal from the noise detector. The two band-pass filters can either be controlled by a single common signal, but also by two different signals provided by the noise detector. In the latter case the noise detector can evaluate the noise in at least two different spectral regions and then produce the corresponding control signals. In this way the spectral features of the noise inside the vehicle can be more accurately influenced.

The possibility of the invention to detect the noise level comprises letting the loudspeaker radiate only useful acoustic signals with frequencies above a predetermined cut-off frequency, and letting the noise detector only evaluate that is noise under this predetermined cut-off frequency. The predetermined cut-off frequency is preferably designed to settle at the lower end of the human listening range, so that there is no cut-off of the audible spectrum with lower sounds. On the other hand, a cut-off of the deepest inaudible bass is advantageous with regard to the listener, as well as the loudspeaker and the output stage.

Another possibility is for the noise detector to evaluate noise in at least one area where no, or only a small useful acoustic signal occurs, and where the noise is consistently related to the noise in the listening area. Thus noise detector microphones can be installed for example in the engine compartment, and/or in the wheel wells, and/or in the trunk, and/or in the air supply duct, for example to decrease engine noise, roadway noise, wind noise from the chassis and fan noise, where the useful signal does not occur in the respective areas, or only to such a small degree that it becomes negligible.

The noise situation in the respective areas is consistently related to the noise inside the vehicle, so that the noise levels in the individual areas can provide a very good approximation of the noise situation inside the vehicle.

A preferred alternative to this is for the noise detector to evaluate an audio signal which is composed of a useful acoustic signal and noise in the listening area, and the useful electric signal provided directly or indirectly by the signal source, where the noise signal portion in the audio signal is determined and provided to the other sound volume adjuster for the production of the control signal. Consequently the noise situation in the listening area is captured directly, and the useful acoustic signal and/or the noise are then extracted from the total signal by the evaluation, so that the latter can be used to produce the control signal.

In that case the noise detector preferably comprises a sound receiver for the production of an electric audio signal from the useful acoustic signal, and from the superimposed noise in the listening area, also an extractor connected downstream of the sound receiver for extracting the noise portion contained in the audio signal, and a control device connected downstream of the extractor which receives the noise portion of the audio signal and at least one signal that is derived from the audio signal, and from both produces the control signal for the other sound volume adjuster.

Here a signal that is derived from the audio signal can either correspond to the useful signal portion of the audio signal, but also to the sum of the useful signal portion and the noise portion of the audio signal.

The extractor advantageously provides the signal that is derived from the audio signal in order to achieve greater accuracy.

Preferred versions of an extractor contain at least one adaptive filter. In that case the extractor can be connected to the signal source and obtain the useful electric signal from it. However as an alternative the extractor can also be connected to the input of the loudspeaker (or to an upstream amplifier for example) and receive the useful electric signal from there.

In a further development of the invention the adaptive filter comprises a filtering unit with delay elements, and a coefficients network which is coupled to the delay elements and by means of filtering produces an output signal from the audio signal that is supplied to it. A control unit is additionally provided for control of the coefficients network, so that the output signal is optimized with respect to a reference signal, where filtering elements with adjustable phase angles are preferably provided as the delay elements, and the phase angles are adjusted to produce a distorted frequency resolution. In that case the output signal of the adaptive filter is used to produce the control signal for the other sound volume adjuster. The advantage is that filters with a distorted frequency resolution and with comparable accuracy are available at a clearly lower cost than conventionally constructed filters.

Here the useful electric signal is provided as the reference signal and is either taken from the output circuit of the signal source or from the loudspeaker input circuit.

All-pass filters are preferably used as the filtering elements with adjustable phase angles. The optimization of the output signal in the adaptive filter, and especially in the adaptive filter with distorted frequency resolution, takes place by means of the least mean square error method (or the delayed least mean square error method).

The installation for the tone-compensated adaptation of the transmission function comprises in particular a loudness filtering device for boosting the lower audio frequency range with respect to the middle audio frequency range. In this case the loudness filtering device comprises for example at least one low-pass filter and/or one band-pass filter, which is established in the range of about 200 Hz and boosts the lower audio frequency range.

The adaptation of the loudness filtering device in accordance with the adjusted sound volume and/or the existing noise can take place by changing the filter quality of at least one filter (band-pass, low-pass) of the loudness filtering device. In addition or as an alternative the filter cut-off frequency of at least one filter (low-pass, band-pass) of the loudness filtering device can be adapted as a function of the noise level (except also as a function of the adjusted sound volume level). Furthermore and to help the tone-compensated adaptation of the transmission function, the loudness filtering device can contain at least one more filter for boosting the lower audio frequency range with respect to the middle audio frequency range where, to help the tone-compensated adaptation of the transmission function, the individual filters are switched on or off as a function of the noise level (except also as a function of the adjusted sound volume level).

In a further development of the invention the tone-compensated adaptation of the transmission function includes a filtering device which is controlled by the useful electric signal for the frequency-selective filtering of the useful electric signal, a first controllable attenuator connected downstream of the filtering device, a second controllable attenuator which is also controlled by the audio signal, an adder which is connected to both attenuators to produce a tone-compensated output signal, and a control element which is connected to both attenuators to control these in accordance with a preset sound volume.

Finally the filtering device can comprise a predetermined phase response, where a phase shifting device which is installed before the second attenuator and is also controlled by the useful electric signal, is provided to produce a phase response which equals the filtering device.

In the following the invention will be explained in greater detail by means of embodiments represented by the figures of the drawing, where:

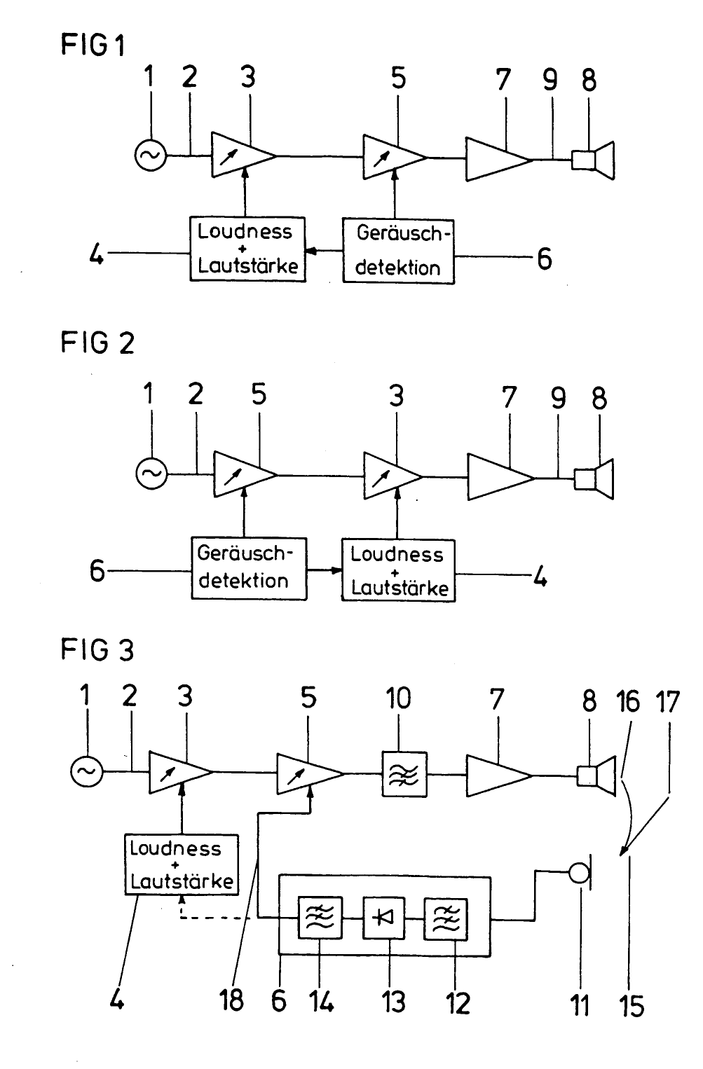

FIG. 1: is a first general embodiment of an arrangement according to the invention;

FIG. 2: is an alternative version of the general version in FIG. 1;

FIG. 3: is a version of an arrangement according to the invention which uses different frequency ranges for noise detection and useful signal;

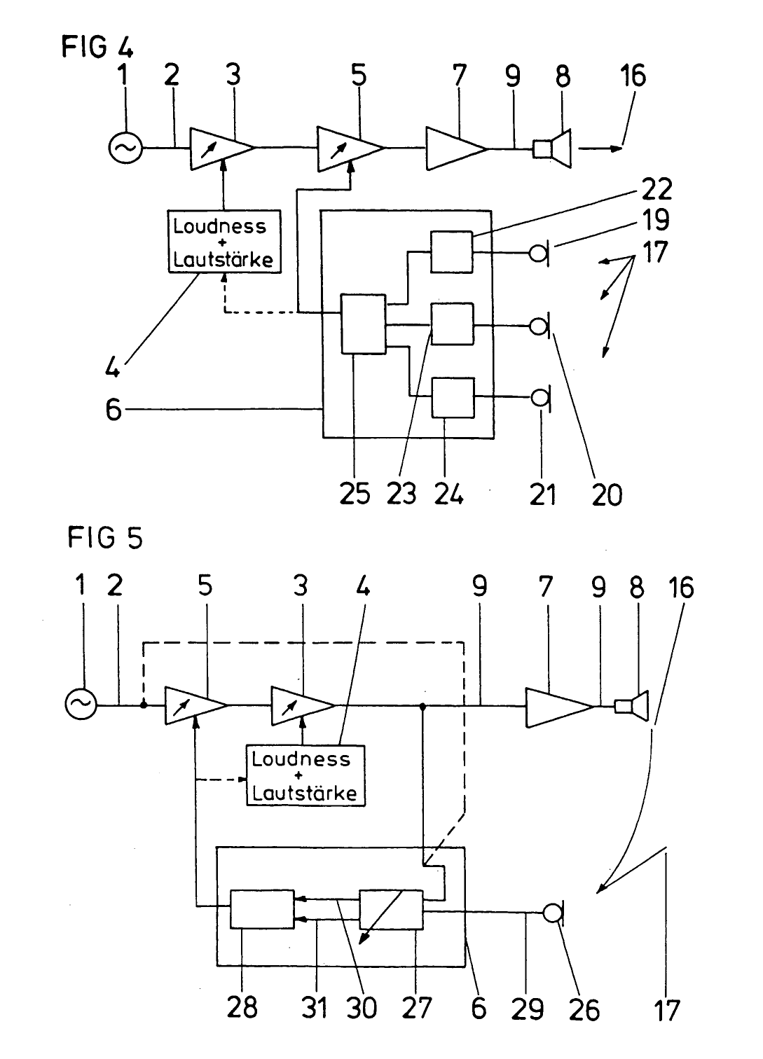

FIG. 4: is a version of an arrangement according to the invention with noise detection in different areas;

FIG. 5: is a version of an arrangement according to the invention with noise detection in the listening area and extraction of a useful signal portion and a noise portion from the audio signal;

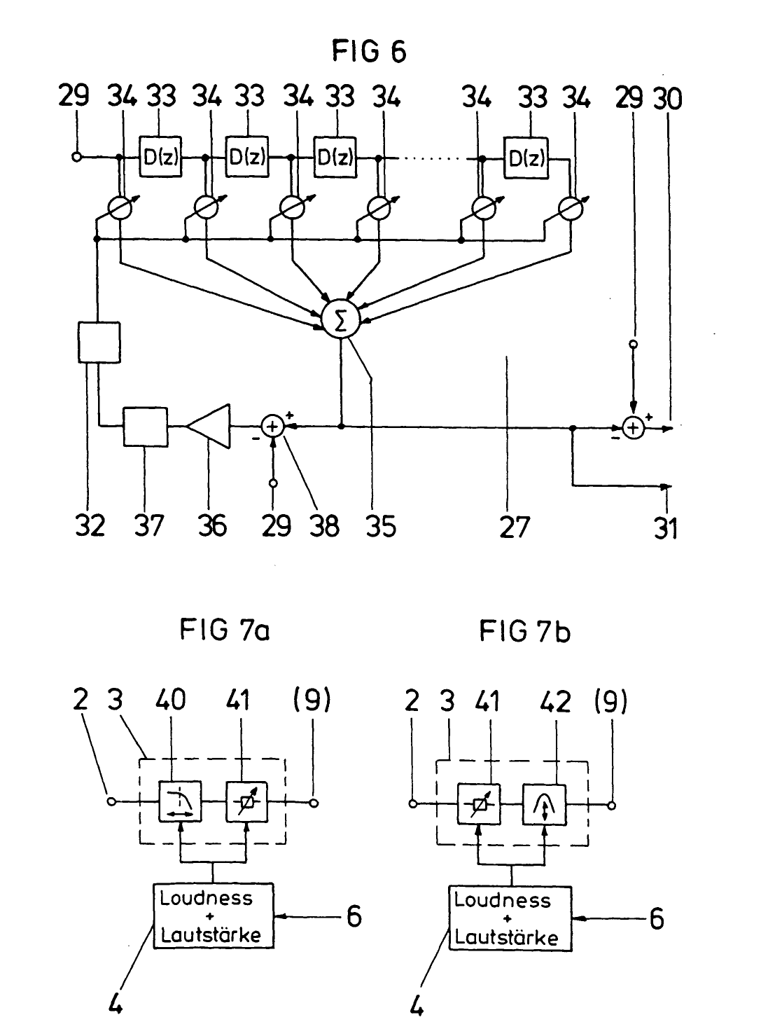

FIG. 6: is a version of a preferred adaptive filter for use with the arrangement in FIG. 5;

FIG. 7: is a device for the tone-compensated adaptation of the transmission function in an arrangement according to the invention;

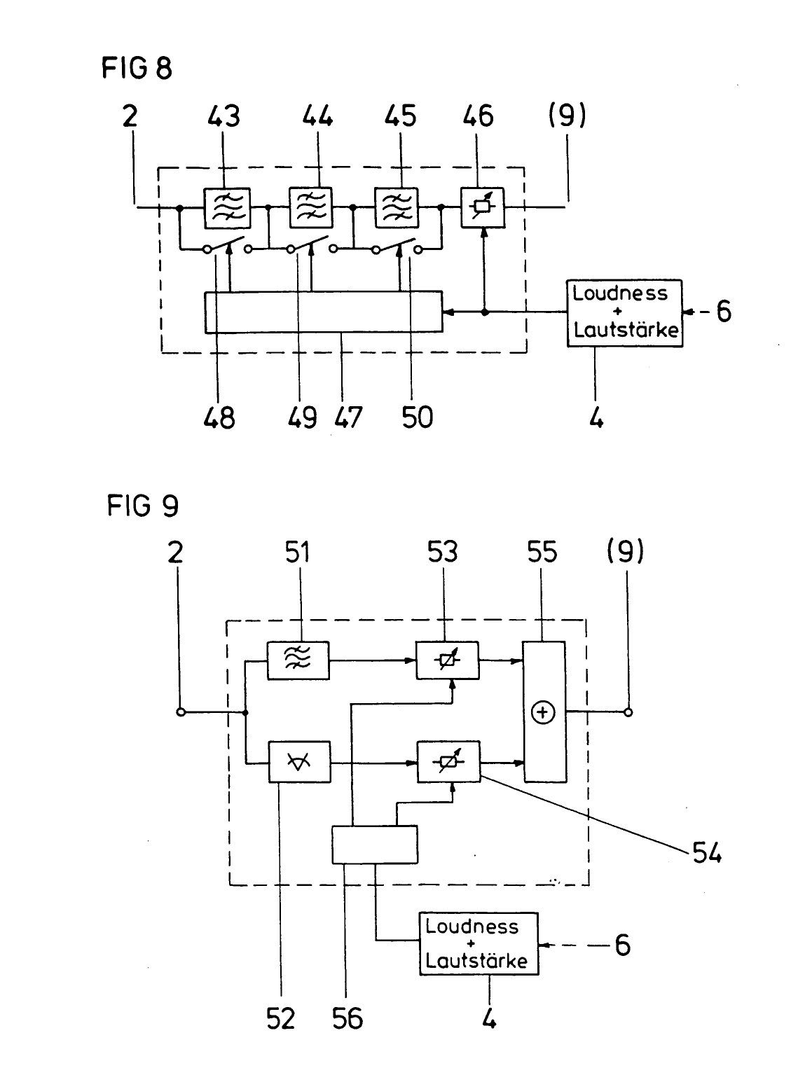

FIG. 8: is a first alternative version of an arrangement according to FIG. 7, and

FIG. 9: is a second alternative version of an arrangement according to FIG. 7.

In the general version of an arrangement according to the invention shown in FIG. 1, a signal source 1 emits a useful electric signal 2 that is supplied to a sound volume adjuster 3 which can be adjusted by an operator. In a further development of the invention, not only can the loudness adjuster 4 change the sound volume, but can at the same time perform a tone-compensated (loudness) adaptation of the transmission behavior of the sound volume adjuster 3 as a function of the sound volume adjustment. Another sound volume adjuster 5, which can be controlled by a noise detector 6, follows the sound volume adjuster 3. The noise detector 6 determines the noise level in the listening area by means of a direct or indirect measurement, and from it produces a control signal for the sound volume adjuster 5. An amplifier 7 for control of a loudspeaker 8 follows the sound volume adjuster 5. In this case the amplifier 7 and the loudspeaker 8 can be installed separately, or together for example they can form an active loudspeaker. To develop the invention further in this case the loudness adjuster 4 is additionally controlled by the noise detector.

The embodiment in FIG. 2 is derived from the arrangement shown in FIG. 1, in that the sequence of both sound volume adjusters 3 and 5 is reversed. But the control of the sound volume adjusters 5 and 3 is performed in the same way by the noise detector 6 or the loudness adjuster 4. The processed useful electric signal 9 at the loudspeaker 8 is the same—assuming equal adjustments of the sound volume adjusters 5 and 3 and the same useful electric signal 2—and is therefore again the same as in FIG. 1.

Starting with the embodiment in FIG. 1, the version shown in FIG. 3 contains a high-pass 10 which is installed between the sound volume adjuster 5 and the amplifier 7. However the high-pass 10 could also be installed in any place between the signal source 1 and the loudspeaker 8. The high-pass 10 could possibly also be omitted if sufficient bass tone attenuation is provided either in the transmission chain between the signal source 1 and the loudspeaker 8, or in the loudspeaker 8 itself. Here the cut-off frequency of the low pass filter 10 (sic) is preferably the lower audibility limit of the human hearing, therefore at 20 Hz for example, so that the high-pass 10 does not adulterate the subjective sound impression.

According to the invention the noise detector 6 acquires the noise portion in the listening area with the low pass filter at the same or at a lower cut-off frequency. To that end by means of a microphone 11 in the listening area the noise detector acquires an audio signal 15 which is composed of the useful acoustic signal from the loudspeaker 8 and a noise 17. In the simplest case the noise detector 6 can be composed of a low pass filter 12 with a cut-off frequency that corresponds approximately to the high-pass 10, and it can be followed by a rectifier unit 13 with a subsequent smoothing low pass filter 14, which together detect peak values for example. In the same way the mean value or the root mean square value can also be used for the evaluation. A control signal 18 obtained in this manner can then be used to control the sound volume adjuster 5.

The embodiment in FIG. 4 is derived from the version shown in FIG. 1 in that the noise detector 6 has three microphones 19, 20, 21 which are located in areas where only the interference noise or parts thereof occur, but where the useful acoustic signal 16 from loudspeaker 8 is not present. Here the noise which occurs at the microphones 19, 20 and 21 is representative of the noise which occurs in the listening area. The microphones 19, 20 and 21 are preferably installed in the engine compartment, in the wheel wells, in the trunk or in the air supply ducts. By means of respective level measuring devices 22, 23, 24, which either detect the peak values, their mean value, their root mean square value or their level, the signals from the microphones 19, 20, 21 are subsequently weighted accordingly and added up for example in an evaluation device 25.

In that case the evaluation device 25 in turn provides the control signal 18. This arrangement therefore starts with the assumption that the noise signal in the places of the microphones 19, 20 and 21 is clearly higher than the useful acoustic signal 16 provided by the loudspeaker 8 in these areas.

Starting with the general version of an arrangement according to the invention shown in FIG. 2, the noise detector 6 in FIG. 5 is designed as an adaptive filter 27 with a downstream connected comparator 28. Here the adaptive filter 27 receives the listening signal 29 which is acquired by the microphone 26 in the listening area. In this case the listening signal 29 is composed of a part that comprises the useful acoustic signal 16 from the loudspeaker 8 and a noise portion derived from the noise in the listening area.

The adaptive filter 27 now filters the reference signal (2, 9) in a way so that the listening signal 29 is divided into a noise signal portion 30 and a useful signal portion 31. A comparator device 28 compares the noise signal portion 30 and the useful signal portion 31 with each other and controls the sound volume adjuster 5 as a function of how the two behave with respect to each other. In this case the reference signal for the adaptive filter 27 can either be a signal in the signal branch before the sound volume adjusters 3 and 5, or a signal in the signal branch behind the sound volume adjusters 3 and 5, thus e.g. the useful electric signals 2, 9. But it is also possible to pick up the signal between the two sound volume adjusters 3 and 5.

In a simple (not shown) version, the adaptive filter 27 can be designed to filter out only the noise portion 30. The filtered out noise signal portion 30 is then used to directly control the sound volume adjuster 5, without using the comparator stage 28. However the advantage of the above used comparator stage 28 lies in that most of the so-called gain-chase behavior is suppressed. A gain chase behavior is therefore due to the fact that a residual portion of the useful signal is contained in the noise signal portion 30, which increases the measured noise level with respect to the actual portion. Because of the higher noise level, the useful signal level is then increased by the sound volume adjuster 5, which in turn leads to an increase in the residual portion of the useful signal in the noise signal portion. A new increase in the useful signal level takes place and so forth, until the maximum sound volume has been reached. The comparator 28 can then be used to determine the actual increase or lack thereof, thus preventing a gain-chase behavior.

FIG. 6 shows an embodiment of a preferred adaptive filter 27 from FIG. 5. The reference signal (2, 9) in the adaptive filter 27 shown in FIG. 6 is supplied to a chain of series-connected delay elements 33, where signals are picked up from their inlet or outlet taps and supplied to an adder 35 via controllable coefficient elements 34. The useful signal portion 31 can then be picked up from the outlet of the adder 35. But by interchanging the input signals of the adaptive filter 27, the noise signal portion could also be available at the outlet of the adder for further processing.

The control of the coefficient elements 34 takes place in accordance with the least mean square error method. To that end the signal at the outlet of the adder 35 is subtracted from the listening signal 29 by means of a subtracter 38 and supplied to an amplifier 36. In general the embodiment uses not only the least mean square error method (LMS), but in particular the delayed least mean square error method. To that end a delay unit 37 and an LMS control unit 32 are connected downstream of the amplifier 36, and their output signal is then used to control the coefficient elements 34. The present embodiment determines the noise signal portion 30 by simply subtracting the useful signal portion 31 from the listening signal 29 by means of a subtracter 39.

In a further development of the invention, the embodiment shown in FIG. 6 uses delay elements 33 that have adjustable phase angles, such as for example all-pass filters, where the phase angles are adjusted so as to achieve a distorted frequency resolution of the adaptive digital filter 27. In addition to the version of the embodiment with the finite impulse response filters (FIR), infinite impulse response filters or wave digital filters can also be used in the same way. Furthermore instead of the least mean square error method, any other desired optimization method can be used.

The advantage of using delay elements with adjustable phase angles as opposed to simple delay elements lies in the fact that the filter cost can be considerably reduced. In this way such (warped) filters can also advantageously process frequency ranges with high significance at high resolution, and frequency ranges with low significance at low resolution. A given filter can accordingly be optimally realized for a limited cost.

Delay elements with an adjustable phase angle such as all-pass filters are characterized by the following transmission function D(z) during the discrete time z:

D(z)=(z⁻¹−λ)/(1−λz⁻¹)

The phase angle π of the filter element can be adjusted by means of the filter coefficient λ of the all-pass filter. However the filter coefficient of the all-pass filter can also be used to adjust the frequency distortion function of the adaptive filter 27 (warping parameter). In the transmitted sense and with the help of the phase characteristic of the all-pass filters, which is known to depend exclusively on its coefficient λ, the linear frequency axis can be converted into a new (sic) distorted (warped) frequency axis. A resolution behavior can be realized in this case which corresponds for example to the human hearing, and has a higher resolution with low tones than with high ones.

FIG. 7 shows two alternative examples of the sound volume adjuster 3 version, which can be used by itself as well as in combination with the other.

The example in FIG. 7a comprises a low pass filter 40, whose cut-off frequency as well as an attenuator 41 can be controlled by the loudness adjuster 4. The control takes place in a way so that the lower the sound volume level to be adjusted by means of the attenuator 41 is, meaning when its attenuation is greater, and thus when the noise level that is determined by the noise detector 6 is higher, the higher as well is the cut-off frequency of the low pass filter 40. In this case the typical range of the low pass filter 40 cut-off frequency lies between 50 Hz and 300 Hz. The low pass filter 40 can be preceded by a high-pass which however is not shown in FIG. 7a, to compensate for a bass boost which lies outside of the hearing range.

As an alternative to the version shown in FIG. 7a and in accordance with FIG. 7b, a band-pass filter 42 with a fixed mid-frequency can be used instead of the low pass filter 40, where its quality is controlled by the loudness adjuster 4 in accordance with the attenuator 41. In the embodiment of FIG. 7b the sequence of attenuator 41 and band-pass filter 42 is interchanged with respect to the one in FIG. 7a. Regardless of that however, the quality of the low pass filter 40 and the cut-off frequency of the band-pass filter 42 can additionally be changed according to the attenuation adjustment of the attenuator 41. The control of the band-pass filter 42 quality takes place as a function of the sound volume level and the noise level determined by the noise detector 6, so that on the basis of a relatively low mid-frequency the quality is reduced at lower sound volume levels and/or at higher noise levels.

In another version of a sound volume adjuster 3, according to FIG. 8 three band-pass filters (and/or low pass filters) 43, 44, 45 are connected in series with each other and with an attenuator 46. Controllable switches 48, 49, 50 are connected via a comparator 47 in parallel with the band-pass filters 43, 44, 45 and are controlled by the comparator as a function of the control signal provided by the control unit 4 for the attenuator 46, so that in the presence of large sound volume levels and/or small noise levels all the switches bypass the band-pass filters 43, 44, 45, and in the presence of low sound volume levels and/or large noise levels all the 43, 44, 45 are active. In between the band-pass filters 43, 44, 45 are switched on or off in accordance with the desired loudness curve. In addition to the indicated serial structure of the band-pass filters 43, 44, 45, a corresponding parallel structure can also be used in the same manner.

FIG. 9 shows another preferred version of a sound volume adjuster 3. In this embodiment the useful signal 2 is supplied both to a band-pass filter 51 and to an (optional) phase correction circuit 52. Here the useful signal 2 is available at the maximum possible level. A controllable attenuator 53 or 54 is respectively installed downstream of the band-pass filter 51 and the phase correction circuit 52. Finally the outputs of the attenuators 53 and 54 are connected to the inputs of an adder 55, from the output of which the attenuated and loudness corrected useful signal is available.

The control of the controllable attenuators 53 and 54 takes place by means of a control circuit 56, which adjusts the attenuators 53 and 54 as a function of a corresponding control signal from the loudness adjuster 4. In this case the control of the attenuators 53 and 54 takes place in such a way that at high sound volume levels and/or low noise levels, meaning that with low-attenuation by the attenuator 54, the attenuator 59 produces a high attenuation. When the attenuation by the attenuator 54 increases, the attenuation by attenuator 59 decreases, namely to the degree needed to fulfill the requested loudness curve. Starting from a predetermined point, the attenuations by both attenuators 52 (sic) and 54 then increase, while the attenuation by attenuator 54 increases clearly more than the one by the attenuator 53.

1. A device for the noise-dependent adjustment of the sound volume of a loudspeaker (8) which is fed a useful electric signal (2, 9) from a signal source (1) in a listening area filled with noise (17), with two sound volume adjuster (3, 5) connected in series to each other and between the signal source (1) and the loudspeaker (8), one of which (3) can be controlled manually and the other (5) by a control signal (18), and a noise detector (6) to determine the level of the noise (17) and produce the control signal (18) for the other sound volume adjuster (5) in accordance with the level of the noise (17).

2. A device for the noise-dependent adjustment of the sound volume as claimed in claim 1, wherein the one manually controllable sound volume adjuster (3) is coupled to the adjusted sound volume by a device (4) for the tone-compensated adaptation of the transmission function between the signal source (1) and the loudspeaker (8).

3. A device for the noise-dependent adjustment of the sound volume as claimed in claim 1, wherein a device (4) for the tone-compensated adaptation of the transmission function is connected between the signal source (1) and the loudspeaker (8), and where the device (4) for the tone-compensated adaptation is controlled by at least one (further) control signal from the noise detector (6).

4. A device for the noise-dependent adjustment of the sound volume as claimed in claim 2 or 3, wherein the device (4) for the tone-compensated adaptation of the transmission function contains at least two filters (43, 44, 45) with different cut-off/mid-frequencies, each of which is respectively controlled by a control signal (18) from the noise detector (6).

5. A device for the noise-dependent adjustment of the sound volume as claimed in one of claims 1 to 4, wherein the noise detector (6) evaluates the noise in at least two different spectral regions and produces commensurate control signals (18).

6. A device for the noise-dependent adjustment of the sound volume as claimed in one of claims 1 to 5, wherein a useful acoustic signal (16) that is emitted by the loudspeaker (8) comprises signals with frequencies above a predetermined cut-off frequency, and the noise detector (6) evaluates noise below this predetermined cut-off frequency.

7. A device for the noise-dependent adjustment of the sound volume as claimed in one of claims 1 to 5, wherein the noise detector (6) evaluates noise (17) in at least one area in which no, or only a small useful acoustic signal (16) takes place, and where the noise has a fixed relation to the noise (17) in the listening area.

8. A device for the noise-dependent adjustment of the sound volume as claimed in one of claims 1 to 5, wherein the noise detector (6) evaluates an audio signal (15) that is composed of a useful acoustic signal (16) and noise (17) in the listening area, and of the useful electric signal (2, 9) provided by the signal source (1).

9. A device for the noise-dependent adjustment of the sound volume as claimed in claim 8, wherein the noise detector (6) comprises a sound receiver (26) for producing an electric audio signal from the useful acoustic signal (16) and the superimposed noise (17) in the listening area, an extractor (27) which is connected downstream of the sound receiver (26) for extracting the noise portion (17) contained in the audio signal (15), and a control element (28) which is connected downstream of the extractor (27) and receives the noise portion (30) of the audio signal (15) and at least one signal (31) that is derived from the audio signal (15), and from both produces the control signal (18) for the other sound volume adjuster (5).

10. A device for the noise-dependent adjustment of the sound volume as claimed in claim 9, wherein a signal (31) that is derived from the audio signal (15) corresponds to the useful signal portion (16) of the audio signal (15).

11. A device for the noise-dependent adjustment of the sound volume as claimed in claim 9, wherein a signal (31) that is derived from the audio signal (15) corresponds to the sum of the useful signal portion (16) and the noise portion (17) of the audio signal (15).

12. A device for the noise-dependent adjustment of the sound volume as claimed in claim 9, 10 or 11, wherein the extractor (27) provides a signal (31) which is derived from the audio signal (15).

13. A device for the noise-dependent adjustment of the sound volume as claimed in one of claims 9 to 12, wherein the extractor (27) contains at least one adaptive filter (29 to 38).

14. A device for the noise-dependent adjustment of the sound volume as claimed in one of claims 9 to 13, wherein the extractor (27) is connected to the signal source (1) from which it receives the useful electric signal (2, 9).

15. A device for the noise-dependent adjustment of the sound volume as claimed in one of claims 9 to 13, wherein the extractor (27) is connected to the input of loudspeaker (8), from where it receives the useful electric signal (2, 9).

16. A device for the noise-dependent adjustment of the sound volume as claimed in one of claims 13 to 15, wherein the adaptive filter comprises delay elements (33) and a coefficients network (34) which is coupled to the delay elements (33) and produces an output signal (31) by filtering the supplied audio signal (15), and a control unit (36, 37, 38) for controlling the coefficients network (34) in a way so that the output signal (31) is optimized with respect to a reference signal (2, 9), where filter elements with adjustable phase angles are provided as delay elements (33), and the phase angles are adjusted to produce a distorted frequency resolution, where the output signal (31) is used to produce the control signal (18).

17. A device for the noise-dependent adjustment of the sound volume as claimed in claim 16, wherein the useful electric signal (2, 9) is provided as the reference signal (32).

18. A device for the noise-dependent adjustment of the sound volume as claimed in claim 16 or 17, wherein all-pass filters are provided as filter elements with adjustable phase angles.

19. A device for the noise-dependent adjustment of the sound volume as claimed in one of claims 13 to 18, wherein the optimization of the output signal (31) is carried out by means of the least mean square error method.

20. A device for the noise-dependent adjustment of the sound volume as claimed in one of claims 2 to 15, wherein the device for the tone-compensated adaptation of the transmission function contains a loudness filtering device (40 to 56) for boosting the lower audio frequency range with respect to the middle audio frequency range.

21. A device for the noise-dependent adjustment of the sound volume as claimed in claim 16, wherein the tone-compensated adaptation of the transmission function requires the filtering quality of the loudness filtering device (40 to 56) to be adapted as a function of the noise level.

22. A device for the noise-dependent adjustment of the sound volume as claimed in claim 20 or 21, wherein the tone-compensated adaptation of the transmission function requires the filter cut-off frequency of the loudness filtering device (40 to 56) to be adapted as a function of the noise level.

23. A device for the noise-dependent adjustment of the sound volume as claimed in claim 20, wherein the device for the tone-compensated adaptation of the transmission function requires that the loudness filtering device (40 to 56) contains at least two filters (43, 44, 45) for boosting the lower audio frequency range with respect to the middle audio frequency range, and the tone-compensated adaptation of the transmission function requires these individual filters, (43, 44, 45) to be switched on or off as a function of the noise level.

24. A device for the noise-dependent adjustment of the sound volume as claimed in one of claims 2 to 18, wherein the device for the tone-compensated adaptation of the transmission function comprises a filtering device (51) which is controlled by the useful electric signal (2, 9), for the frequency-selective filtering of the latter, a first controllable attenuator (53) which is connected downstream of the filtering device (51), a second controllable attenuator (54) which is also controlled by the useful electric signal (2, 9), an adder (55) which is connected to both attenuators (53, 54) for producing a tone-compensated output signal, and a control element (56) which is connected to both attenuators (53, 54) for controlling the two attenuators (53, 54) in accordance with a predetermined sound volume and/or a noise level.

25. A device for the noise-dependent adjustment of the sound volume as claimed in claim 24, wherein the filtering device (51) includes predetermined phase behavior, and wherein a phase shifter (52), which is also controlled by the useful electric signal (2, 9), is provided and produces a phase behavior that is identical to the filtering device (51) and which is connected upstream of the second attenuator (54).
